(19) United States
(12) Patent Application Publication
(10) Pub. No.: US 2024/0312966 A1
(43) Pub. Date: Sep. 19, 2024

(54) ELEMENT TRANSFER DEVICE USING FLUIDIC SELF-ASSEMBLY AND DISPLAY DEVICE

(71) Applicant: Chung Ang University Industry Academic Cooperation Foundation, Seoul (KR)

(72) Inventors: Jaesoo YOO, Seoul (KR); Yongtae KO, Gyeonggi-do (KR)

(73) Assignee: Chung Ang University Industry Academic Cooperation Foundation, Seoul (KR)

(21) Appl. No.: 18/591,325

(22) Filed: Feb. 29, 2024

(30) Foreign Application Priority Data
Mar. 16, 2023 (KR) 10-2023-0034591
May 15, 2023 (KR) 10-2023-0061940

(51) Int. Cl. H01L 25/075

(52) U.S. Cl. CPC H01L 25/0753

(57) ABSTRACT

An element transfer device is provided. The element transfer device includes a cartridge including a plurality of element recesses each having a shape corresponding to a shape of a micro element, at least one wave energy generator configured to supply wave energy to the cartridge, a camera, and a processor. The processor is configured to primarily arrange a plurality of micro elements in the plurality of element recesses by supplying the wave energy to the cartridge accommodating the plurality of micro elements disposed in a fluid, obtain a first image by photographing the cartridge, and based on the first image, control a waveform and a frequency of the wave energy and control a secondary arrangement of disposing the micro elements in remaining element recesses in which the micro elements are not disposed.

### CROSS-REFERENCE TO RELATED APPLICATION

This application is based on and claims priority under 35 U.S.C. § 119 to Korean Patent Application Nos. 10-2023-0034591, filed on Mar. 16, 2023, and 10-2023-0061940, filed on May 12, 2023, in the Korean Intellectual Property Office, the disclosures of which are incorporated by reference herein in their entirety.

### BACKGROUND

### 1. Field

An embodiment of the disclosure relates to an element transfer device for transferring a micro element to a substrate by using a fluidic self-assembly (FSA). In addition, an embodiment of the disclosure relates to a display device including a substrate fabricated using an element transfer device.

This study was supported by the Samsung Future Technology Development Project. (Task number: SRFC-IT2201-02)

### 2. Description of the Related Art

There is a need for a technology of transferring a functional micro element to a specific position on a specific substrate (a silicon substrate, a plastic substrate, fiber, etc.) for a desired purpose. The fabrication of micro elements has been commercialized without much difficulty due to the development of semiconductor processes. However, a process of transferring a micro element to a desired substrate has many limitations due to the small size of the micro element. Considering that the thickness of hair is about 50 μm to about 100 μm, it is not easy to freely integrate and package a unit element having a size of about 50 μm at a specific location. Of the industries that are trying to utilize micro elements, the industry group closest to commercialization is the display-related industry. For the commercialization and mass production of micro light-emitting diode (LED) displays, there is a high demand for a micro element transfer technology in the display field.

### SUMMARY

According to an embodiment of the disclosure, an element transfer device is provided. The element transfer device includes a cartridge including a plurality of element recesses each having a shape corresponding to a shape of a micro element, at least one wave energy generator configured to supply wave energy having a certain frequency to the cartridge, a camera configured to photograph a disposition state of the micro element on the cartridge, and a processor configured to control the at least one wave energy generator. The processor is further configured to primarily arrange a plurality of micro elements in the plurality of element recesses by supplying the wave energy to the cartridge accommodating the plurality of micro elements disposed in a fluid, obtain a first image by photographing the cartridge, for which the primary arrangement is completed, by using the camera, and based on the first image, control a waveform and frequency of the wave energy supplied from the at least one wave energy generator and control a secondary arrangement of disposing the micro elements in remaining element recesses in which the micro elements are not disposed from among the plurality of element recesses.

The processor may be further configured to input an input vector obtained from the first image to a first machine learning model, obtain output frequency information output from the first machine learning model, and control the at least one wave energy generator to output wave energy of the output frequency information.

The processor may be further configured to recognize at least one remaining micro element not disposed in an element recess from the first image, recognize at least one remaining element recess in which a micro element is not disposed, and input the input vector including a position of the at least one remaining micro element and a position of the at least one remaining element recess to the first machine learning model and obtain the output frequency information output from the first machine learning model.

The first machine learning model may be a model trained using at least one of Proximal Policy Optimization (PPO), Trust Region Policy Optimization (TRPO), Advantage Actor Critic (A2C), and Deep Q Network (DQN) algorithm.

The first machine learning model may be primarily trained using first learning data, wherein the processor may be further configured to obtain a vector field representing movement of the plurality of micro elements according to an output frequency of the at least one wave energy generator from the first image, and update the first machine learning model by reinforcement learning of the first machine learning model by using secondary learning data including a vector field of the plurality of micro elements and an output frequency of the at least one wave energy generator.

The processor may be further configured to calculate an error between a vector field of the plurality of micro elements corresponding to an input vector of the first machine learning model and a vector field of the plurality of micro elements obtained from the first image, calculate an evaluation compensation based on the error, and perform reinforcement learning on the first machine learning model based on the evaluation compensation.

The processor may be further configured to obtain the first image for each first period, determine a waveform and an output frequency of wave energy, output from the at least one wave energy generator, based on the first image for each first period, and control the at least one wave energy generator to output wave energy having the determined waveform and output frequency.

The at least one wave energy generator may include a plurality of wave energy generators disposed around the cartridge, and the processor may be further configured to control a waveform and an output frequency of the wave energy of each of the plurality of wave energy generators.

Each of the plurality of micro elements may have a 180-degree symmetry, include a cathode electrode at a center of the micro element, include a first anode electrode on an upper side of the cathode electrode, and include a second anode electrode on a lower side of the cathode electrode, and the plurality of element recesses may have shapes corresponding to shapes of the plurality of micro elements.

Each of the plurality of micro elements may have an asymmetric shape in which top, bottom, left, and right sides are distinguished from each other, and include one anode and one cathode, and the plurality of element recesses may have shapes corresponding to shapes of the plurality of micro elements.

Each of the plurality of micro elements may include a circular disk and a protrusion disposed in a center of a first surface of the circular disk, a first electrode may be formed on the protrusion and a second electrode is formed on the circular disk, and the plurality of element recesses may have shapes corresponding to a shape of a second surface of the circular disk opposite to the first surface.

The cartridge may include an align key formed on the cartridge to identify an arrangement state of the cartridge, and the processor may be further configured to recognize the align key of the cartridge from the first image and obtain image data of an area corresponding to the cartridge based on the recognized align key.

The wave energy may correspond to an acoustic streaming signal.

The element transfer device may further include an element transfer jig (i.e., a chip transfer jig) including at least one hole and configured to transfer the plurality of micro elements onto the cartridge through the hole.

The element transfer device may further include an element dispersing device configured to disperse the plurality of micro elements by tilting the cartridge, wherein the processor may be further configured to, after the plurality of micro elements are supplied to fluid on the cartridge through the element transfer jig, control the element dispersing device to disperse the plurality of micro elements by tilting the cartridge, and perform the primary arrangement after the plurality of micro elements are dispersed on the cartridge by the element dispersing device.

The processor may be further configured to determine whether transfer of the micro element to each of the plurality of element recesses has been completed based on the first image captured by photographing the cartridge in which the micro elements are secondarily arranged, and repeat the secondary arrangement until transfer of the micro element to each of the plurality of element recesses is completed.

The element transfer device may further include a transfer module configured to transfer the plurality of micro elements disposed in the cartridge to a substrate, wherein the transfer module may be further configured to remove remaining micro elements on the cartridge where arrangement of the micro elements is completed, place the substrate on the cartridge to transfer the plurality of micro elements disposed on the cartridge to the substrate, and bond the micro elements transferred to the substrate to the substrate.

The plurality of micro elements may correspond to light-emitting diode (LED) elements, and the LED elements disposed on the cartridge may be transferred to a substrate of a display device.

The plurality of micro elements may have a size of 100 micrometers (μm) or less.

According to an embodiment of the disclosure, there is provided a display device including a light-emitting diode (LED) substrate produced by arranging a plurality of LED elements on the cartridge by using the element transfer device of claim 1 and transferring the plurality of LED elements arranged on the cartridge to a substrate, wherein the plurality of LED elements have a size of 100 micrometers (μm) or less.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a diagram illustrating a structure of an element transfer device according to an embodiment;

FIG. 2 is a block diagram illustrating a structure of an element transfer device according to an embodiment;

FIG. 3 is a diagram illustrating structures of a wave energy generator and a jig according to an embodiment;

FIG. 4 is a diagram illustrating structures of a wave energy generator and a jig according to an embodiment;

FIG. 5 is a diagram illustrating a method of delivering wave energy to a cartridge according to an embodiment;

FIG. 6 is a diagram illustrating a waveform of wave energy according to an embodiment;

FIG. 7 is a diagram illustrating an example of a waveform at a beat frequency according to an embodiment;

FIG. 8 is a graph showing a filling rate over time during transfer of micro elements to a cartridge, according to an embodiment;

FIG. 9 is a flowchart illustrating a process of performing a primary arrangement operation and a secondary arrangement operation by an element transfer device, according to an embodiment;

FIG. 10 is a diagram illustrating a process of performing a primary arrangement operation and a secondary arrangement operation, according to an embodiment;

FIG. 11 is a diagram illustrating a process of performing a secondary arrangement operation based on a first image, according to an embodiment;

FIG. 12 is a diagram illustrating a cartridge on which an align key is formed, according to an embodiment;

FIG. 13 is a diagram illustrating a process of obtaining output frequency information from a first image, according to an embodiment;

FIG. 14 is a diagram illustrating a learning environment of a first machine learning model according to an embodiment;

FIG. 15 is a diagram illustrating an object recognition process according to an embodiment;

FIG. 16 is a diagram illustrating a process of obtaining a target path vector, according to an embodiment;

FIG. 17 is a diagram illustrating an input and an output of a first machine learning model according to an embodiment;

FIG. 18 is a diagram illustrating a process of learning of a first machine learning model, according to an embodiment;

FIG. 19 is a diagram illustrating a vector field according to an embodiment;

FIG. 20 is a diagram illustrating a process of performing secondary learning, according to an embodiment;

FIG. 21 is a diagram illustrating a structure of a micro element according to an embodiment;

FIG. 22 is a diagram illustrating a structure of a micro element according to an embodiment;

FIG. 23 is a diagram illustrating a structure of a micro element according to an embodiment;

FIG. 24 is a diagram illustrating a shape of a micro element according to an embodiment;

FIG. 25 is a diagram illustrating a process of transferring micro elements from a cartridge to a substrate and bonding the micro elements to the substrate, according to an embodiment; and

FIG. 26 is a diagram illustrating a display device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

Hereinafter, principles and embodiments of the disclosure will be described in detail in order to fully convey the scope of the disclosure and enable one of ordinary skill in the art to embody and practice the disclosure. The embodiments may be implemented in various forms.

The same reference numerals denote the same elements throughout the specification. All elements of embodiments are not described in the specification, and descriptions of matters well known in the art to which the disclosure pertains or repeated descriptions between embodiments will not be given. Terms such as “part” and “portion” used herein denote those that may be implemented by software or hardware. According to embodiments, a plurality of parts or portions may be implemented by a single unit or element, or a single part or portion may include a plurality of units or elements. Hereinafter, embodiments of the disclosure and operation principles of the embodiments will be described with reference to the accompanying drawings.

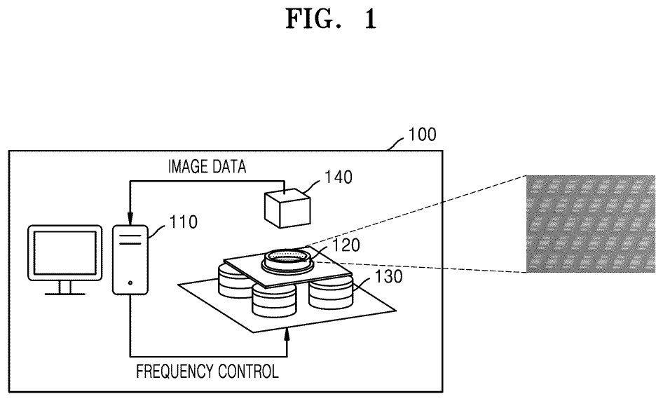

FIG. 1 is a diagram illustrating the structure of an element transfer device 100 according to an embodiment.

In order to move an element to a desired position in a fluidic self-assembly (FSA) process, it is necessary to accurately control a force applied to the element. The magnitude of the force applied to the element is greatly influenced by the shape and size of the element. When simply considering the magnitude of the force, in the case of a mini light-emitting diode (LED) element with a size of 100 μm or more, gravity, a surface tension, a fluid drag force, and an inertial force have orders of magnitude of about 500 μN. For elements with a size of less than 50 μm and a thickness of less than 10 μm, the surface tension is dominant.

According to an embodiment, in the FSA, a large number of micro elements may be arranged on a substrate in a desired manner by controlling a force applied to the micro elements (e.g., LED chips). In an embodiment, in addition to various forces acting on the micro element during FSA, wave energy is used as external energy to control the behavior of the micro element. The wave energy may be generated using an actuator, a transducer using lead zirconate titanate (PZT), a speaker, or the like. According to an embodiment, the element transfer device 100 controls the behavior of an element by using a magnitude and direction of an acoustic streaming force generated from an acoustic streaming signal generated by a generated wave energy in a fluid. The acoustic streaming force is a force generated by wave energy at an acoustic wave frequency. The acoustic wave frequency ranges from about 20 Hz to about 2,000 Hz. According to an embodiment, an acoustic streaming signal in a range of about 50 Hz to about 200 Hz may be used. When the acoustic streaming signal is applied in a fluid, wave energy is transmitted to the fluid. The element transfer device 100 according to an embodiment drives elements in a desired direction by transforming a waveform of wave energy transmitted to a fluid. That is, the element transfer device 100 may drive elements in a desired direction by controlling the magnitude and direction of an acoustic streaming force by using a processor 110.

Examples of the micro element include various functional elements. The micro element may correspond to an element having a micro-scale size of 100 μm or less. Examples of the micro element may include light emitting and receiving elements for blockchain, microelectromechanical system (MEMS) elements, micro switches, light-emitting diodes (LEDs), image sensors, biosensors, quartz-based oscillators, and the like.

The element transfer device 100 according to an embodiment may transfer a micro element onto a cartridge 120 by using an FSA method. The element transfer device 100 may transfer the micro element transferred on the cartridge 120 to a certain substrate to manufacture the substrate on which the micro element is transferred. The cartridge 120 may include a plurality of element recesses into which a micro element is transferred. The substrate may include, for example, a silicon substrate, a plastic substrate, a fiber, a thin-film transistor (TFT)-backplane, a stretchable substrate, or the like. According to an embodiment, the element recesses may have a size difference of 17% or less from the micro element to match the micro element.

According to an embodiment, the element transfer device 100 transmits wave energy to the cartridge 120 by using a wave energy generator 130. In a state where the cartridge 120 accommodates a plurality of micro elements distributed in a fluid, the plurality of micro elements move in a certain direction by the wave energy transmitted to the cartridge 120. The plurality of micro elements are inserted into the element recesses of the cartridge 120 and transferred onto the cartridge 120. The element recesses are formed in a shape corresponding to the shape of the micro elements. The micro elements are inserted into the element recesses and fixed.

According to an embodiment, the element transfer device 100 disperses the micro elements in the cartridge 120 by using wave energy and primarily arranges the micro elements in the cartridge 120.

Thereafter, the element transfer device 100 uses a camera 140 to photograph the cartridge 120 in which the micro elements are primarily arranged. A processor 110 of the element transfer device 100 obtains information about the micro element transfer state of the cartridge 120 by using a first image captured by the camera 140.

The processor 110 detects remaining micro elements and empty remaining element recesses on the cartridge 120 based on the first image. The processor 110 controls the element transfer device 100 to fill all the element recesses of the cartridge 120 by moving the remaining micro elements to the empty remaining element recesses. The processor 110 determines the frequency and waveform of wave energy to be output from the wave energy generator 130 based on the first image. According to an embodiment, the processor 110 may determine the frequency and waveform of wave energy from the first image by using a first machine learning model.

The element transfer device 100 outputs wave energy of the determined frequency and waveform to the cartridge 120 and performs a secondary arrangement operation in which the remaining micro elements are transferred to the remaining empty element recesses by the wave energy. The processor 110 controls the wave energy generator 130 to output wave energy of a determined frequency and waveform. The secondary arrangement operation is repeated until all element recesses of the cartridge 120 are filled.

When the secondary arrangement operation of the cartridge 120 is completed, the element transfer operation to the cartridge 120 is completed. Thereafter, a washing process is performed to remove remaining micro elements and fluid from the cartridge 120. When the washing process of the cartridge 120 is completed, a process of transferring the micro elements transferred to the cartridge 120 to a substrate is performed.

According to an embodiment, transfer of micro elements is possible without limiting a panel size, from small panels to large panels. For example, embodiments of the disclosure may be applied to both the manufacture of a small display module and the manufacture of a large display module. For example, the embodiments of the disclosure may be applied to manufacturing a large display, such as an 84-inch UHD 4K class display (resolution 3840*2160, 8,294,400 pixels, and dpi 484 μm). Such a large display includes a total of 24 million light source elements including about 8 million of each of red, blue, and green light source elements. In order to produce such a large display, it is required to accurately arrange micro-sized light source elements on a display panel. Even if 1,000 elements are transferred per second, it takes more than 6 hours to produce one panel, and the panel manufacturing process takes up a large portion of the production cost. According to an embodiment, the transfer accuracy may be improved and a short process time (i.e., time at completion (TAC)) is possible, thereby reducing the time and cost of manufacturing a large display panel and reducing the ratio of defective pixels.

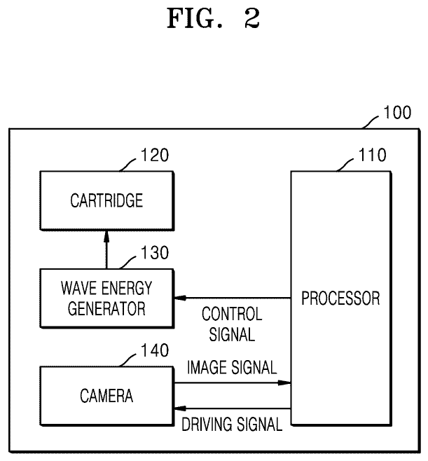

FIG. 2 is a block diagram illustrating the structure of an element transfer device 100 according to an embodiment.

The element transfer device 100 according to an embodiment includes a processor 110, a cartridge 120, a wave energy generator 130, and a camera 140.

The processor 110 controls overall operations of the element transfer device 100. The processor 110 may be implemented as one or more processors. The processor 110 may perform a certain operation by executing an instruction or command stored in a memory (not shown). Also, the processor 110 controls the operations of components included in the element transfer device 100. The processor 110 may include at least one or a combination of a Central Processing Unit (CPU), a Graphics Processing Unit (GPU), and a Neural Processing Unit (NPU).

The cartridge 120 is a device that moves micro elements and transfers them to element recesses by using an FSA method. The cartridge 120 may correspond to an interposer.

The cartridge 120 includes element recesses for fixing micro elements. The element recesses may be arranged in a certain pattern. For example, the element recesses may be arranged in a two-dimensional array form. A pattern of the element recesses may be determined to correspond to a pattern in which micro elements are disposed on a substrate to be fabricated.

Each of the element recesses has a shape corresponding to the shape of each of the micro elements. In addition, the element recess is formed to have a step difference from the upper surface of the cartridge 120 to accommodate the micro element, and is formed in an intaglio shape. According to an embodiment, the micro element has an asymmetric shape. When the micro element has an asymmetric shape, the element recess also has an asymmetric shape corresponding to the micro element.

The cartridge 120 has a fluid accommodating structure capable of accommodating fluid on an area where the element recess is disposed. For example, the fluid accommodating structure may be implemented in the form of a partition wall forming a space accommodating fluid on the upper surface of the cartridge 120. The fluid accommodating structure may correspond to a chunk. For example, the fluid may correspond to ethanol.

The wave energy generator 130 supplies wave energy to the cartridge 120. The wave energy generator 130 is placed in contact with cartridge 120. The wave energy generator 130 may contact the cartridge 120 outside the cartridge 120. The number of wave energy generators 130 may be one or plural. When the element transfer device 100 includes a plurality of wave energy generators 130, the wave energy generators 130 are disposed to contact certain points on the periphery of the cartridge 120.

The wave energy generator 130 is disposed at a position where the wave energy generator 130 is capable of efficiently transmitting wave energy to a fluid accommodating structure (e.g., a jig) of the cartridge 120. The wave energy transmitted from the wave energy generator 130 has to be able to form standing waves well in the cartridge 120. Whether a standing wave is formed depends on boundary conditions of a substrate (i.e. cartridge) in which an applied pulse signal (frequency) and a waveform are generated. A waveform generated by the cartridge 120 may vary according to the boundary conditions. This is related to an eigen value, and is formed when a synthesized wave in the cartridge 120 has the eigen value of a wave signal. Wave energy applied as an external force to the micro element is transmitted by changing the position of a nodal line of the wave. That is, the micro elements are gathered at a place where the pressure is low, and the wave energy generator 130 induces the movement of the micro elements, gathered at the place where the pressure is low, by changing the position of the nodal line. The change of the nodal line may be induced through a change in the wavelength of the wave, a change in the amplitude thereof, or generation of a synthesized wave.

According to an embodiment, the element transfer device 100 includes two wave energy generators 130. The two wave energy generators 130 may be disposed at both ends of the cartridge 120 and may be symmetrically disposed around the center of the cartridge 120.

According to an embodiment, the element transfer device 100 includes four wave energy generators 130. Four wave energy generators 130 are disposed outside the cartridge 120, and each pair are disposed to face each other. For example, the four wave energy generators 130 may be arranged such that their placement points form a rhombus or a rectangle.

The wave energy generator 130 generates wave energy by using, for example, an actuator, a transducer using PZT, a speaker, or the like. The wave energy generator 130 may generate and output a certain standing wave.

The processor 110 controls the wave energy generator 130. The processor 110 controls the on/off of the wave energy output of the wave energy generator 130, the waveform of the wave energy, and the frequency of the wave energy. When the element transfer device 100 includes a plurality of wave energy generators 130, the processor 110 may determine the waveform and wave energy frequency of wave energy of each of the plurality of wave energy generators 130, and may control each of the plurality of wave energy generators 130.

The element transfer device 100 may further include an amplifier (not shown) that amplifies a driving signal of the wave energy generator 130 output from the processor 110 and outputs the amplified driving signal to the wave energy generator 130. The processor 110 generates a pulse signal for controlling the waveform of the wave energy of the wave energy generator 130. The processor 110 may generate a pulse signal by using a certain function generator. The amplifier amplifies the pulse signal output from the processor 110. The amplifier outputs the amplified pulse signal to the wave energy generator 130.

The processor 110 may control the behavior of the micro element by adjusting the waveform, frequency, magnitude, direction, and the like of the standing wave output from the wave energy generator 130. The processor 110 may set a target movement path of the micro element and control the wave energy generator 130 to move the micro element to the target movement path.

For a primary arrangement operation, the processor 110 outputs wave energy through the wave energy generator 130 to disperse the micro elements on the cartridge 120. While moving on the cartridge 120, the micro elements may be fixed to the remaining empty element recesses and transferred to the cartridge 120.

For a secondary arrangement operation, the processor 110 controls the wave energy generator 130 based on a first image captured using the camera 140. The processor 110 controls a photographing operation of the camera 140. Also, the processor 110 controls the waveform and frequency of the wave energy, output through the wave energy generator 130, based on the first image captured by the camera 140. The processor 110 may determine a target path to move the micro element based on the first image. The processor 110 determines the magnitude and direction of the force induced by the wave energy to move the micro element along the target path. The processor 110 determines the waveform and frequency of the wave energy output from each of the plurality of wave energy generators 130 so as to generate a force having a magnitude and a direction corresponding to a target path by a synthesized wave of standing waves output from the plurality of wave energy generators 130.

The camera 140 photoelectrically converts incident light to generate an electrical image signal. The camera 140 may include at least one lens, a lens driving unit, and an image sensor. The camera 140 may include one or more cameras. The camera 140 generates captured image data and outputs it to the processor 110.

The camera 140 may be arranged to photograph an upper surface of the cartridge 120 on which micro elements are disposed in the cartridge 120. The camera 140 may be fixed at a certain position to face the upper surface of the cartridge 120. The camera 140 may be arranged such that a field of view (FOV) may be adjusted, that is, a photographing direction may be adjusted.

The processor 110 may control the camera 140 to capture the first image by the camera 140 after the primary arrangement operation is completed. The processor 110 may control a photographing operation of the camera 140 based on a user input. The first image may correspond to a still image or a moving image.

According to an embodiment, the camera 140 may capture a plurality of first images corresponding to a plurality of still images at certain intervals or based on a user input. The processor 110 may obtain micro element transfer state information at each time point based on the plurality of first images.

Also, according to an embodiment, the camera 140 may capture a first image corresponding to a moving image. The processor 110 may extract a frame image from the first image at a certain period and obtain micro element transfer state information of the cartridge 120 based on the extracted frame image.

Based on the first image, the processor 110 may recognize remaining element recesses on the cartridge 120 to which micro elements have not yet been transferred, and remaining micro elements that have not yet been transferred to element recesses. The processor 110 obtains position information of remaining element recesses and remaining micro elements. The processor 110 determines the waveform and frequency of the wave energy output from the wave energy generator 130 based on the position information of the remaining element recesses and the position information of the remaining micro elements.

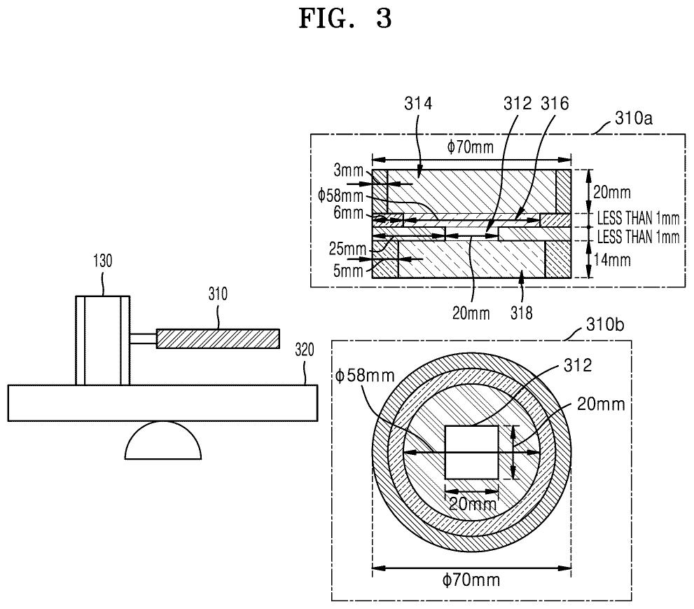

FIG. 3 is a diagram illustrating the structures of a wave energy generator and a jig according to an embodiment.

According to an embodiment, the element transfer device 100 further includes a jig 310 disposed in contact with the wave energy generator 130. In FIG. 3, reference numeral 310a represents a cross-sectional view of the jig 310 and reference numeral 310b represents a top view of the jig 310.

The wave energy generator 130 is disposed on a base substrate 320. The jig 310 is fixed to one side of the wave energy generator 130. For example, the jig 310 may be fixed to the top or side of the wave energy generator 130. Wave energy output from the wave energy generator 130 is transferred to the jig 310. When wave energy is transmitted to the jig 310, a standing wave is formed in the jig 310, and the nodal change of the standing wave moves the micro element. A change in the standing wave waveform changes the nodal position of waveforms, and this change applies a force to the micro element, causing the micro element to move. The processor 110 may move the micro element to a desired position by using a priori known waveform among numerous waveforms.

The jig 310 is mounted with a cartridge 120 in which micro elements may be arranged. The jig 310 may have a certain accommodating structure in which the cartridge 120 may be mounted.

The cartridge 120 is a substrate having a patterned intaglio on which a micro element may be mounted. According to an embodiment, when the micro element is a mini-LED having a size of 70 μm or more, the cartridge 120 may have a structure mounted on the jig 310 by placing an elastic film on a glass substrate and placing a Fine Metal Mesh (FMM) on the elastic film. In addition, according to an embodiment, when the micro element corresponds to a micro LED, the cartridge 120 may have a structure mounted on the jig 120 by making an intaglio pattern directly on a silicon substrate.

When wave energy is output from the wave energy generator 130, force is applied to the micro element on the jig 310, as described above. By the force and direction applied to the micro element by the wave energy, the micro element moves in an intaglio pattern of the cartridge 120 and settles in an intaglio that matches the shape of the micro element.

According to an embodiment, the jig 310 may have a circular shape. For example, the jig 310 is circular with a diameter of 70 mm. A middle region 316 may be formed in a circular shape. For example, the middle region 316 may be formed in a circular shape with a diameter of 58 mm. A hole 312 may be formed as a rectangle disposed below the middle region 316. For example, the hole 312 may be formed in a square shape having one side of 20 mm. According to an embodiment, the cartridge 120 may be mounted in a hole 312.

According to an embodiment, an inlet region 314 may be formed to a depth of 20 mm. The inlet region 314 may be formed by a partition wall having a thickness of 3 mm. The middle region 316 may be formed to a depth of less than 1 mm. The middle region 316 may be formed by a partition wall having a thickness of 6 mm. The hole 312 may be formed to a depth of less than 1 mm. The hole 312 may be formed by a partition wall having a thickness of 25 mm. A discharge region 318 may be formed by a partition wall having a thickness of 5 mm.

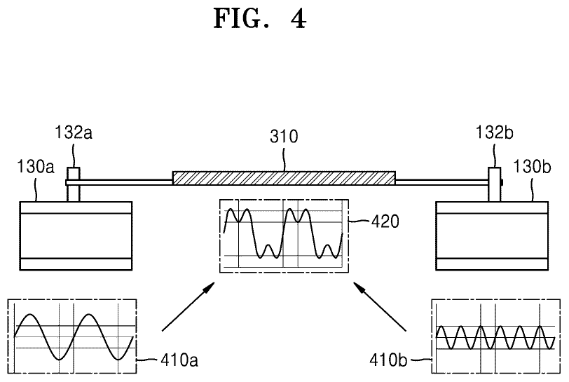

FIG. 4 is a diagram illustrating the structures of a wave energy generator and a jig according to an embodiment.

According to an embodiment, the element transfer device 100 includes a plurality of wave energy generators 130a and 130b and a jig 310. For example, the element transfer device 100 may include two or four wave energy generators 130a and 130b.

The jig 310 is in contact with the plurality of wave energy generators 130a and 130b and is disposed in a space between the wave energy generators 130a and 130b. The jig 310 may be supported and fixed by the plurality of wave energy generators 130a and 130b. For example, the jig 310 may be supported and fixed by support structures 132a and 132b respectively formed on upper surfaces of the plurality of wave energy generators 130a and 130b.

According to an embodiment, the jig 310 may have a structure in which the inlet region 314, the middle region 316, the hole 312, and the discharge region 318 are formed in order from top to bottom, as shown in FIG. 3.

The wave energy generators 130a and 130b generate and output wave energies of certain wave energy waveforms 410a and 410b, respectively. A first wave energy generator 130a and a second wave energy generator 130b may generate and output wave energies of different wave energy waveforms 410a and 410b. The processor 110 may generate control signals for controlling the wave energy waveforms 410a and 410b and output the control signals to the wave energy generators 130a and 130b. As shown in FIG. 4, the wave energy waveform 410a of the first wave energy generator 130a and the wave energy waveform 410b of the second wave energy generator 130b may have different amplitudes and frequencies. The processor 110 may adjust the sizes, frequencies, and phases of the wave energy waveforms 410a and 410b respectively output from the wave energy generators 130a and 130b.

The wave energies output from the wave energy generators 130a and 130b are transmitted to the jig 310 through the support structures 132a and 132b. In the jig 310, a standing wave of a synthesized waveform 420 generated by combining the wave energy waveforms 410a and 410b of the wave energy generators 130a and 130b is formed. A nodal change of the synthesized waveform 420 formed in the jig 310 occurs, and a force is applied to the micro element due to the nodal change of the synthesized waveform 420, causing the micro element to move.

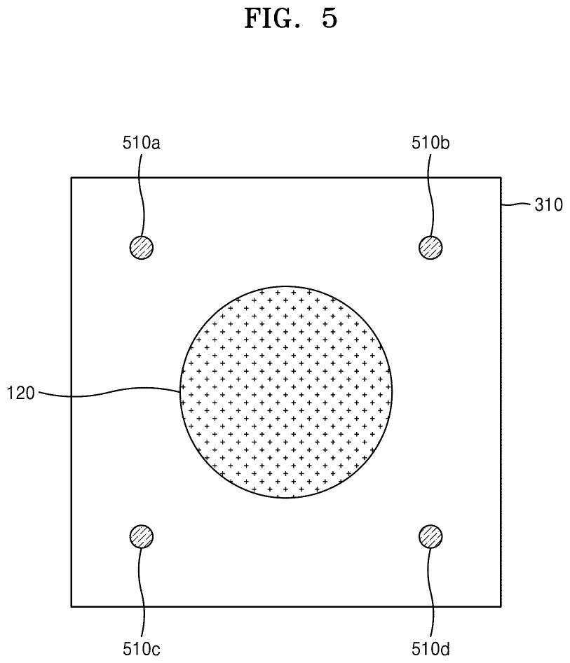

FIG. 5 is a diagram illustrating a method of delivering wave energy to a cartridge according to an embodiment. FIG. 5 is a top view of the cartridge 120 mounted on the jig 310.

According to an embodiment, the element transfer device 100 includes four wave energy generators 130. The four wave energy generators 130 are in contact with four points 510a, 510b, 510c, and 510d of the jig 310 to output wave energy to the cartridge 120. The cartridge 120 includes a fluid accommodating structure at the center thereof. The four points 510a, 510b, 510c, and 510d in contact with the wave energy generators 130 may be symmetrically arranged around the cartridge 120.

In the case of using the four wave energy generators 130, the degree of freedom for synthesizing waveforms is high, and more various synthesized waves may be generated. The processor 110 may generate various synthesized waves by independently adjusting the frequency, intensity, phase, etc. of the waveform of wave energy transmitted from each point.

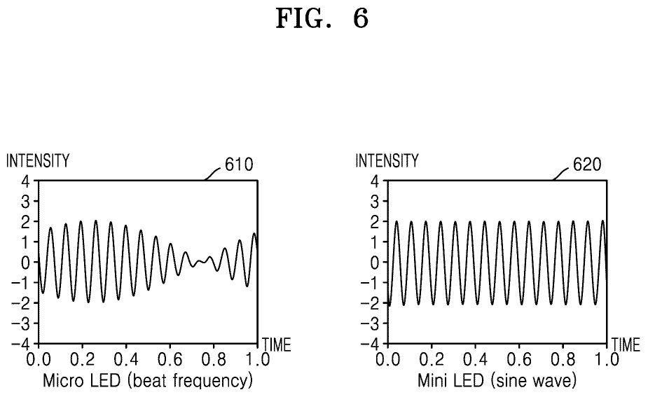

FIG. 6 is a diagram illustrating a waveform of wave energy according to an embodiment.

According to an embodiment, for the movement of the micro element, an output signal of the wave energy generator 130 may be generated such that an synthesized wave of a beat frequency is generated in the cartridge 120 In sound, a beat is an interference pattern between two sounds of slightly different frequencies, and is perceived as a periodic volume change at a rate corresponding to the difference between two frequencies. As shown in FIG. 6, the waveform 610 of wave energy having a beat frequency periodically changes in volume. A waveform of the beat frequency may be generated by synthesizing two sine waves having similar frequencies. According to an embodiment, the two wave energy generators 130 facing each other output wave energies having similar frequencies. In this way, the two wave energy signals having similar frequencies, output from the two wave energy generators 130, are synthesized in the cartridge 120 to generate a standing wave having a beat frequency.

According to an embodiment, a micro element may correspond to a micro LED. The micro LED is an LED chip in units of about 5 μm to about 50 μm. The element transfer device 100 may output two wave energy signals having similar frequencies from the wave energy generators 130 facing each other to thereby generate a standing wave of a beat frequency on the cartridge 120. The micro LED may move on fluid by the standing wave of the beat frequency and be transferred to the cartridge 120.

According to an embodiment, the element transfer device 100 may be used for transferring a mini LED. In the case of transferring the mini LED, the element transfer device 100 may control the wave energy generator 130 to generate a standing wave 620 of a sine wave on the cartridge 120.

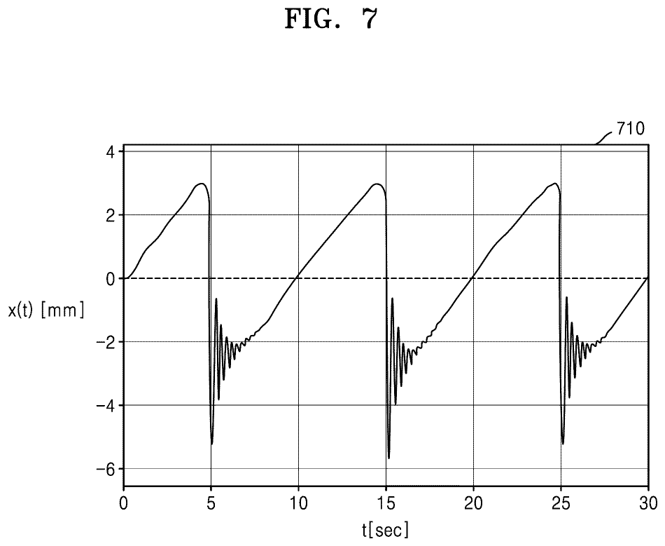

FIG. 7 is a diagram illustrating an example of a waveform of a beat frequency according to an embodiment.

According to an embodiment, a synthesized signal 710 of wave energies output from the plurality of wave energy generators 130 may be generated on the cartridge 120, as shown in FIG. 7. The synthesized signal 710 represents a signal appearing on one axis transverse to the center on a substrate of cartridge 120.

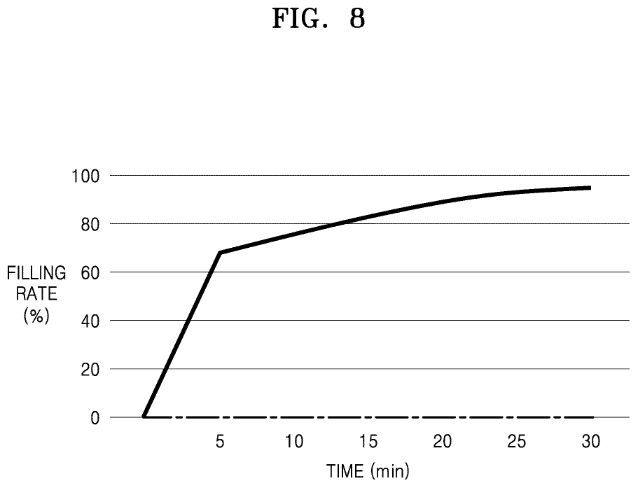

FIG. 8 is a graph showing a filling rate over time while micro elements are transferred to a cartridge, according to an embodiment.

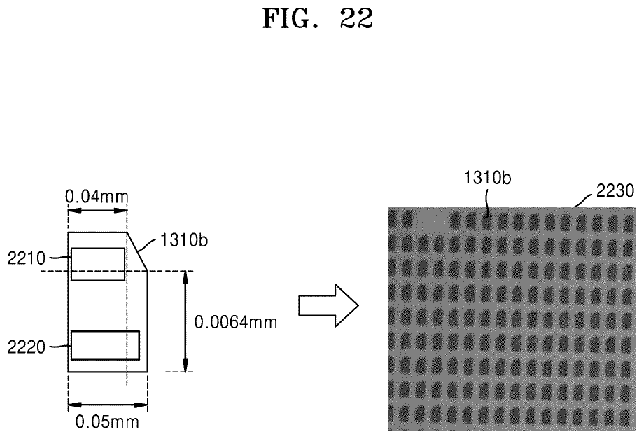

While applying wave energy to the cartridge 120, a filling rate, which is a rate at which micro elements are filled in the element recesses of the cartridge 120, was measured. The filling rate is a value expressing the ratio of the number of element recesses filled with micro elements to the total number of element recesses of the cartridge 120 as a percentage. The filling rate shown in the graph of FIG. 8 was measured using the micro element of the embodiment of FIG. 22 to be described below.

As shown in FIG. 8, the filling rate of the micro element rapidly increased during the initial 5 minutes, and a filling rate exceeding 60% was measured after 5 minutes had elapsed. After that, as the filling of the micro elements continued into the remaining element recesses where the micro elements were not filled, the filling rate was continuously increased up to 30 minutes. When 20 minutes had elapsed, a filling rate exceeding 90% was measured. In an actual experiment, detrapping of the micro elements was observed, and this phenomenon resulted in a decrease in the rate of increase of the filling rate. This problem may be overcome by precisely controlling wave synthesis through fine adjustment of the magnitude of wave energy.

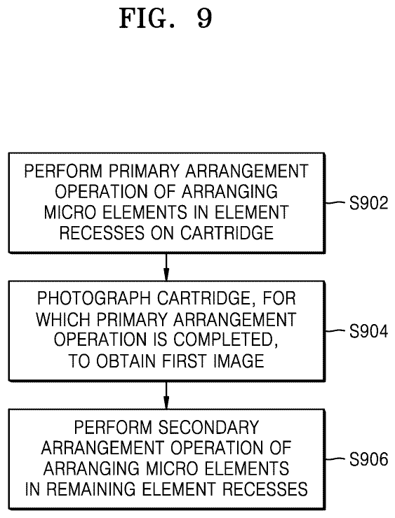

FIG. 9 is a flowchart illustrating a process of performing a primary arrangement operation and a secondary arrangement operation by an element transfer device, according to an embodiment.

According to an embodiment, in Operation S902, the element transfer device 100 supplies micro elements to the cartridge 120 through a jig and then performs a primary arrangement operation of arranging micro elements in element recesses on the cartridge 120. The primary arrangement operation disperses the micro elements within a fluid accommodating space of the cartridge 120. The micro elements are dispersed in the fluid accommodating space of the cartridge 120, filled into empty element recesses, and transferred to the cartridge 120.

According to an embodiment, the primary arrangement operation is performed by wave energy output from the wave energy generator 130. By the wave energy output from the wave energy generator 130, the micro elements in a fluid on the cartridge 120 move. The primary arrangement operation may be performed for a certain time.

When the primary arrangement operation is completed, in Operation S904, the element transfer device 100 photographs the cartridge 120, for which the primary arrangement operation is completed, by using the camera 140 to obtain a first image. The camera 140 may photograph the fluid accommodating space of the cartridge 120 from the top. The first image shows the arrangement state of micro elements in the fluid accommodating space of the cartridge 120. The processor 110 obtains the first image from the camera 140 and obtains arrangement state information of micro elements on the cartridge 120.

Next, in Operation S906, the element transfer device 100 controls the waveform and frequency of the wave energy supplied from the wave energy generator 130 based on the first image, and performs a secondary arrangement operation of arranging micro elements in the remaining element recesses in which micro elements are not disposed.

The element transfer device 100 recognizes the remaining element recesses in which micro elements are not disposed from the first image. Also, the element transfer device 100 recognizes the remaining micro elements not disposed in the element recesses from the first image. The element transfer device 100 determines a target movement path for moving the remaining micro elements to the remaining element recesses based on the positions of the remaining element recesses and the remaining micro elements.

The element transfer device 100 determines a wave energy waveform output from the wave energy generator 130 to generate a standing wave in the fluid of the cartridge 120 to apply a force for moving the micro element along the target movement path to the micro element. The element transfer device 100 may determine the wave energy waveform by determining the magnitude, frequency, phase, and the like of the wave energy. The element transfer device 100 controls the wave energy generator 130 to output the determined wave energy waveform, and performs a secondary arrangement operation of moving the remaining micro elements into the remaining element recesses. The secondary arrangement operation is repeated until transfer of the micro elements into all the element recesses is completed and no remaining element recesses are detected.

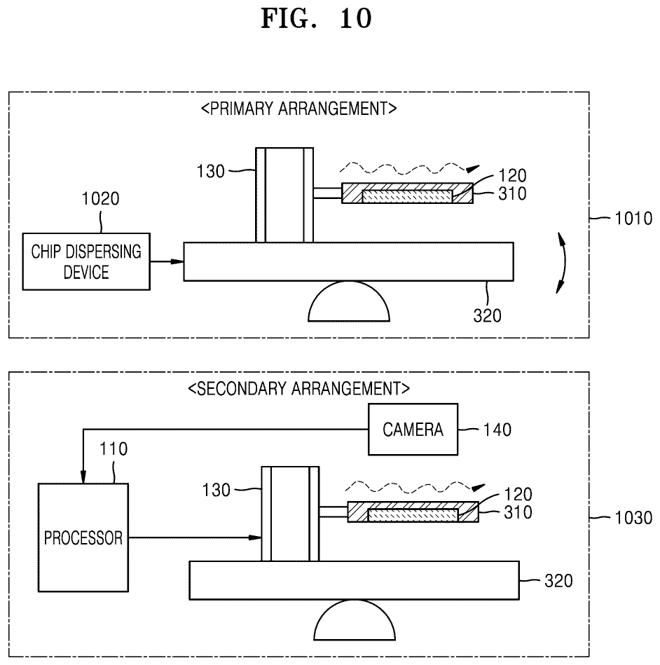

FIG. 10 is a diagram illustrating a process of performing a primary arrangement operation and a secondary arrangement operation, according to an embodiment.

1010 in FIG. 10 represents a primary arrangement operation. According to an embodiment, the element transfer device 100 may move the micro elements by applying gravity to the micro elements in the fluid by tilting the cartridge 120 in a primary arrangement process. To this end, the element transfer device 100 includes a chip dispersing device 1020. The chip dispersing device 1020 may tilt the jig 310 to tilt the cartridge 120 disposed on the jig 310. The chip dispersing device 1020 tilts the jig 310 by tilting a base substrate 320 and induces the inclination of the cartridge 120. When the cartridge 120 is tilted, the fluid and micro elements disposed in the cartridge 120 move under gravity.

The chip dispersing device 1020 may include a motor and a driving device that rotate the base substrate 320 in a certain angular range. The chip dispersing device 1020 may tilt the base substrate 320 by rotating the base substrate 320 up and down at a set angle. The chip dispersing device 1020 may change the tilt angle or direction of the base substrate 320 over time to disperse the micro elements on the cartridge 120.

According to an embodiment, the element transfer device 100 may perform both a tilt dispersion operation by the chip dispersing device 1020 and a vibration dispersion operation by the wave energy output from the wave energy generator 130. The tilt dispersion operation and the vibration dispersion operation may be performed sequentially or simultaneously. For example, the element transfer device 100 may first perform a tilt dispersion operation and then perform a vibration dispersion operation.

1030 of FIG. 10 represents a secondary arrangement operation. When the primary arrangement operation is completed, the element transfer device 100 performs a secondary arrangement operation. In the secondary arrangement operation, the tilt dispersion operation is not performed, and a micro element fine movement operation by the wave energy generator 130 is performed. The element transfer device 100 performs a secondary arrangement operation of moving the remaining micro elements into the remaining element recesses based on the first image captured by the camera 140.

According to an embodiment, after the secondary arrangement operation is completed, a remaining micro element removal operation is performed. The element transfer device 100 may gather and remove the remaining micro elements in one direction by tilting the base substrate 320 to remove the remaining micro elements. The chip dispersing device 1020 induces an inclination of the base substrate 320 by inclining the base substrate 320. The fluid and remaining micro elements disposed on the slope of the base substrate 320 move to the lowest edge of the base substrate 320 under gravity. The element transfer device 100 may collect the remaining micro elements gathered by moving to the lowest edge and remove the remaining micro elements from the base substrate 320.

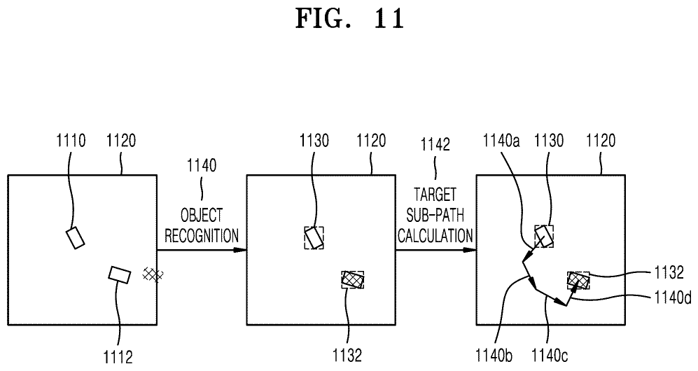

FIG. 11 is a diagram illustrating a process of performing a secondary arrangement operation based on a first image, according to an embodiment.

In FIG. 11, for convenience of description, an example in which one remaining micro element 1110 and one remaining element recess 1112 are detected is shown. However, the embodiment of the disclosure is not limited to the case where there are one remaining micro element 1110 and one remaining element recess 1112, and may also be applied to the case where there are various numbers of remaining micro elements 1110 and remaining element recesses 1112.

The element transfer device 100 performs a secondary arrangement operation when the primary arrangement operation is completed. The element transfer device 100 obtains a first image 120 of the cartridge 120 on which the primary arrangement operation is completed. The first image 1120 may include image data of the remaining micro element 1110 and the remaining element recess 1112.

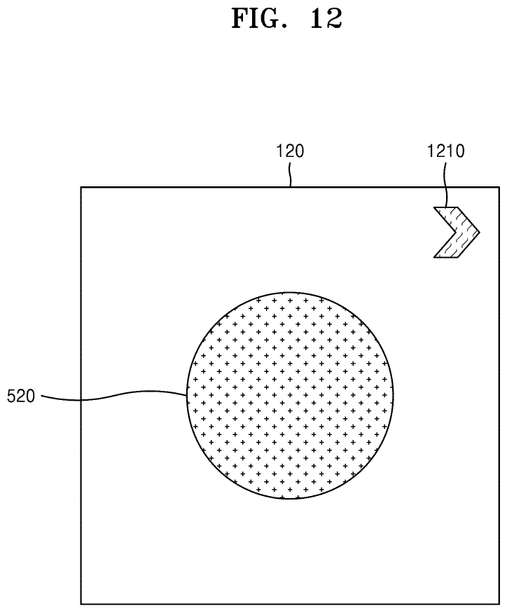

FIG. 12 is a diagram illustrating a cartridge on which an align key is formed, according to an embodiment.

According to an embodiment, an align key 1210 formed on the cartridge 120 may be used to limit an image area in which object recognition is to be performed from the first image 1120.

The cartridge 120 includes an align key 1210 capable of identifying the cartridge 120 from image data and recognizing the arrangement of the cartridge 120. The align key 1210 has an asymmetrical shape such that the direction of the cartridge 120 may be recognized. The align key 1210 is disposed in a certain area on the upper surface of the cartridge 120. The align key 1210 may be printed or attached on the upper surface of the cartridge 120. The align key 1210 may be disposed in a certain area outside a fluid accommodating structure 520. The align key 1210 may be disposed close to an intaglio pattern on which a micro element is seated, and this disposition is advantageous in positioning and arranging the cartridge 120.

The processor 110 recognizes the align key 1210 from the first image 1120. The processor 110 defines an image area to perform object recognition based on the recognized align key 1210. The processor 110 may define a first image area to perform object recognition on the first image 1120 based on the position and direction of the align key 1210, and may rotate and crop the first image 1120 to extract the first image area. By extracting the first image area from the first image 1120 based on the align key 1210, the element transfer device 100 may remove factors (e.g., camera vibration, movement of the camera, etc.) that may cause confusion in the field location data of the camera 140.

Referring again to FIG. 11, the secondary arrangement operation will be described.

In Operation, the processor 110 performs an object recognition process for recognizing the remaining micro element 1110 and the remaining element recess 1112 from the first image area of the first image 1120. The processor 110 may recognize the remaining micro element 1110 and the remaining element recess 1112 by using various object recognition algorithms. For example, the processor 110 may recognize the remaining micro element 1110 and the remaining element recess 1112 from the first image 1120 by using a You Only Look Once (YOLO) v.5 algorithm.

The processor 110 defines, through object recognition processing, an element region 1130 corresponding to the remaining micro element 1110 and a recess region 1132 corresponding to the remaining element recess 1112 from the first image 1120. The processor 110 may define the coordinates of the element region 1130 and the coordinates of the recess region 1132. The coordinates of the element region 1130 and the coordinates of the recess region 1132 may be defined based on a first image region.

Next, in Operation 1142, the processor 110 calculates a target path along which the remaining micro element 1110 will move, based on the recognized element and recess regions 1130 and 1132. The processor 110 calculates a target path for moving the micro element 1110 from the coordinates of the element region 1130 to the coordinates of the recess region 1132. The processor 110 determines a target path by using a combination of force vectors that may be applied to the micro element 1110 by synthesized signals of the plurality of wave energy generators 130. The target path may be defined as a combination of a plurality of target sub-paths 1140a, 1140b, 1140c, and 1140d. For example, the processor 110 110 may calculate a target path through which the micro element 1110 moves from the current position to the remaining element recess 1132 by a combination of the target sub-paths 1140a, 1140b, 1140c, and 1140d.

The processor 110 determines the waveform of the wave energy output through each wave energy generator 130 to sequentially move the micro element 1110 along the target sub-paths 1140a, 1140b, 1140c, and 1140d. The wave energy generator 130 sequentially generates and outputs wave energy for moving the micro element 1110 along each of the target sub-paths 1140a, 1140b, 1140c, and 1140d. The micro element 1110 is moved from its current position to the remaining element recess 1132 by a synthesized signal of wave energy sequentially output.

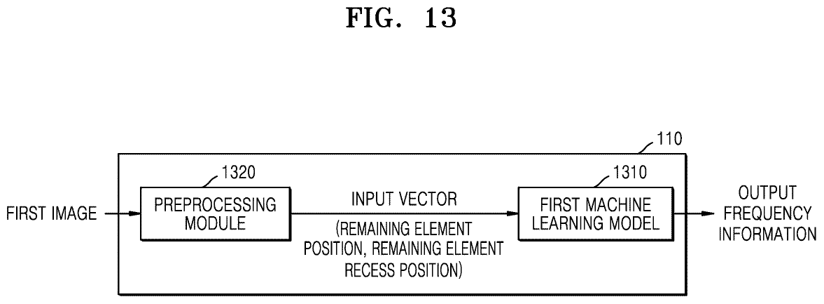

FIG. 13 is a diagram illustrating a process of obtaining output frequency information from a first image, according to an embodiment.

According to an embodiment, the processor 110 obtains output frequency information of wave energy, output from the wave energy generator 130, from the first image by using a first machine learning model 1310.

The processor 110 may generate an input vector from the first image by a preprocessing module 1320. In addition, the processor 110 may generate output frequency information output from the first machine learning model 1310 by inputting the input vector output from the preprocessing module 1320 to the first machine learning model 1310.

The first machine learning model 1310 receives an input vector generated based on the first image and outputs output frequency information. The input vector may include a remaining element position and a remaining element recess position. The input vector may include one or more remaining element positions and one or more remaining element recess positions.

The preprocessing module 1320 generates an input vector from the first image. The preprocessing module 1320 recognizes remaining elements and remaining element recesses from the first image. The preprocessing module 1320 may recognize remaining elements and remaining element recesses by using a certain object recognition algorithm. For example, the preprocessing module 1320 may perform object recognition using the YOLO algorithm. The preprocessing module 1320 generates remaining element position information indicating the coordinates of a recognized remaining element. In addition, the preprocessing module 1320 generates remaining element recess position information indicating the coordinates of the recognized remaining element recess. The preprocessing module 1320 generates an input vector including remaining element position information and remaining element recess position information, and outputs the generated input vector to the first machine learning model 1310.

According to an embodiment, the input vector may include one or more target path vectors composed of coordinate pairs of remaining element positions and remaining element recess positions. The preprocessing module 1320 generates, from one or more remaining element positions and one or more remaining element recess positions, one or more shortest target paths for each remaining element recess. For example, for each remaining element recess, the preprocessing module 1320 may detect a nearest remaining element and calculate a target path through which the nearest remaining element moves to the remaining element recess. The preprocessing module 1320 generates a target path vector for each remaining element recess and generates an input vector including one or more target path vectors. The one or more target path vectors may be simultaneously input to the first machine learning model 1310 in the form of a list or sequentially input to the first machine learning model 1310. The first machine learning model 1310 may generate output frequency information indicating an output frequency of each wave energy generator 130 based on each target path vector. In this case, the first machine learning model 1310 may be a machine learning model trained using learning data including a target path vector and output frequency information.

Also, according to an embodiment, the input vector may include a remaining element position list and a remaining element recess position list. The preprocessing module 1320 generates an input vector including a list of all remaining element positions and a list of all remaining element recess positions without setting a target path. The first machine learning model 1310 generates output frequency information for moving a remaining element to a remaining element recess through an optimal target path based on the input vector. The first machine learning model 1310 may be a machine learning model trained using remaining element position information, remaining element recess position information, and output frequency information.

The processor 110 may periodically obtain a first image, and generate an input vector and calculate first frequency information whenever a new first image is input.

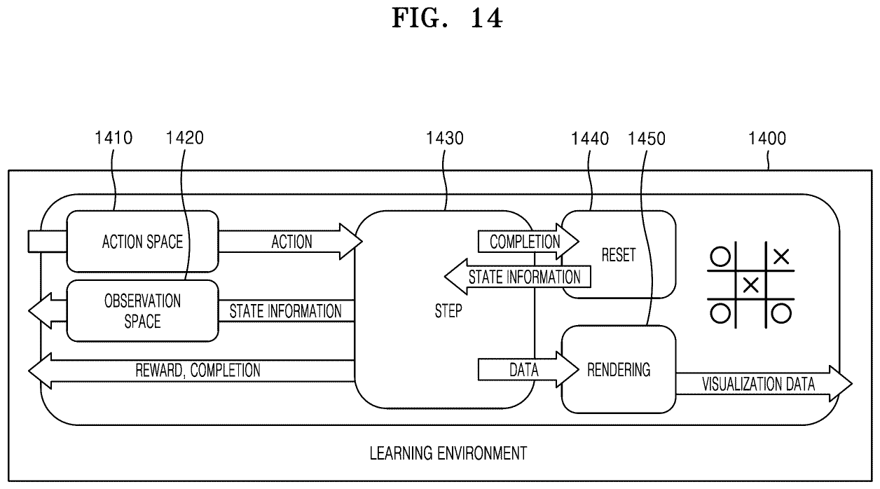

FIG. 14 is a diagram illustrating a learning environment of a first machine learning model according to an embodiment.

According to an embodiment, the first machine learning model 1310 in FIG. 13 may use a Proximal Policy Optimization (PPO) algorithm. The PPO algorithm is a policy-based reinforcement learning method. The PPO algorithm has the advantage of stable learning by learning only in a trustworthy region, which is also an advantage of the Trust Region Policy Optimization (TRPO) algorithm. In addition, the PPO algorithm compensates fo the disadvantages of the TRPO algorithm, which involves complicated and time-consuming calculations, by approximating these disadvantages by methods such as clipping. In addition, the PPO algorithm compensates for the disadvantages of policy gradient learning, reuses learning data, and generates and learns learning data in step units instead of episode units.

Also, according to an embodiment, the first machine learning model 1310 may use at least one of Trust Region Policy Optimization (TRPO), Advantage Actor Critic (A2C), and Deep Q Network (DQN).

The first machine learning model 1310 may be a model trained in a learning environment 1400 shown in FIG. 14. The learning environment 1400 forwards actions from an action space 1410 to a step 1430. The type of action of the first machine learning model 1310 is the frequency of wave energy to be applied. The step 1430 moves a micro element by applying wave energy corresponding to the frequency of the action to the cartridge 120 based on the action. The step 1430 may generate image data obtained by photographing the movement of the micro element and output the image data to an observation space 1420. The observation space 1420 observes the movement of the micro element performed by the step 1430 to generate state information. Observed state information includes a remaining element recess position, a remaining element position, and a target path vector that may be selected from the current position. The step 1430 outputs a reward and completion information when one micro element movement operation is completed. In addition, a reset 1440 performs an initialization operation for performing a next micro element movement operation when completion information is received from the step 1430. The reset 1440 outputs initialized state information to the step 1430. The initialized state information may be position information of the micro element. A rendering 1450 renders data output from the step 1430 into visualization data. The step 1430 may generate state information obtained by photographing the movement of a micro element and output image data to the rendering 1450.

The first machine learning model 1310 is trained using state information and actions, collected based on the learning environment 1400, as learning data. The first machine learning model 1310 is trained to select an optimal action (i.e., output frequency) by learning a policy, which is a function for selecting an action, using the PPO algorithm.

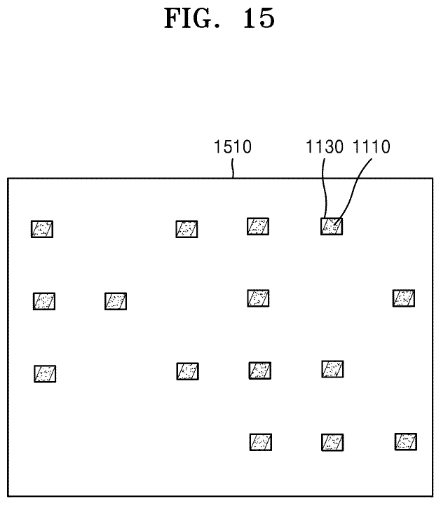

FIG. 15 is a diagram illustrating an object recognition process according to an embodiment.

According to an embodiment, object recognition for recognizing micro elements and element recesses from a first image is performed. The object recognition may be used by the processor 110 of the element transfer device 100 to recognize micro elements and element recesses from the first image. In addition, the object recognition may be used to recognize a micro element from an observation image in a learning process of the first machine learning model. The object recognition may be performed, for example, using various versions of the YOLO algorithm. An object recognition operation may be performed by a device or module that performs learning of the first machine learning model, or may be performed by the processor 110 of the element transfer device 100. In the disclosure, for convenience of description, a process of performing object recognition by the processor 110 with the first image will be mainly described.

According to an embodiment, the processor 110 recognizes a micro element 1110 from a first image 1510. The processor 110 defines an element region 1130 corresponding to the recognized micro element 1110. The processor 110 defines coordinates of the element region 1130 as an element position. The processor 110 may recognize each of the plurality of micro elements 1110, identify coordinates of each micro element 1110, and define a position of each micro element 1110.

According to an embodiment, the micro element 1110 may include an align key. The processor 110 may recognize the micro element 1110 by recognizing an align key of the micro element 1110.

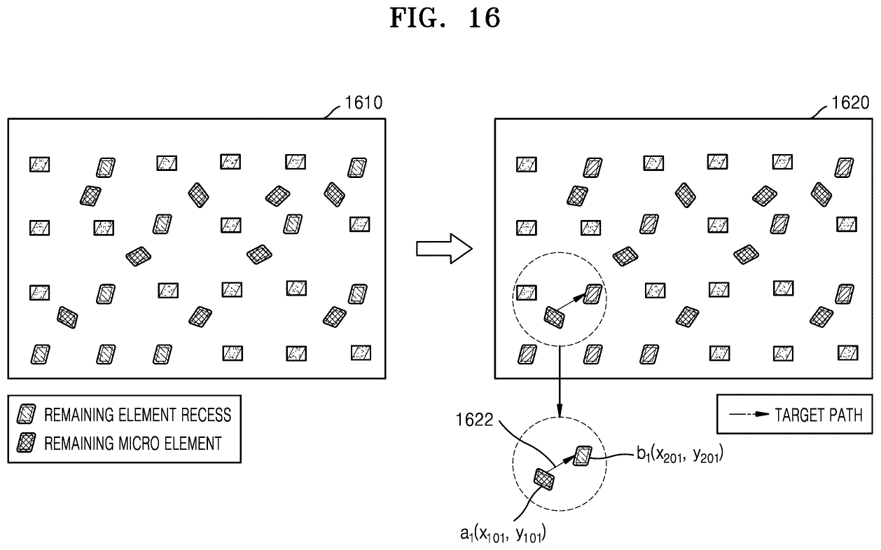

FIG. 16 is a diagram illustrating a process of obtaining a target path vector, according to an embodiment.

According to an embodiment, in Operation 1610, the processor 110 recognizes remaining micro elements and remaining element recesses from a first image. The processor 110 obtains element position information of the remaining micro elements and recess position information of the remaining element recesses.

Next, in Operation 1620, the processor 110 determines a target path for each remaining element recess. The processor 110 may identify a remaining micro element closest to each remaining element recess and set a target path indicating a movement path from the identified micro element to the remaining element recess.

The target path may be represented by a target path vector 1622 defined by the coordinate information (a1 (x₁₀₁, y₁₀₁)) of the micro element and the coordinate information (b1 (x₂₀₁, y₂₀₁)) of the remaining element recess.

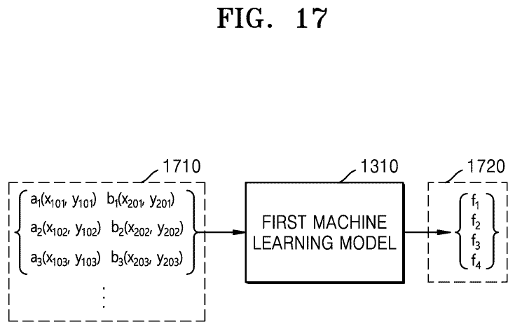

FIG. 17 is a diagram illustrating input and output of a first machine learning model according to an embodiment.

According to an embodiment, the first machine learning model 1310 receives an input vector 1710 including one or more target path vectors, and outputs an output vector 1720 including output frequency information of each wave energy generator 130. In the example of FIG. 17, a case of using four wave energy generators 130 will be described as an example.

An input vector 1710 includes one or more target path vectors defined by element coordinate information a1, a2, and a3 and recess coordinate information b1, b2, and b3. In the example of FIG. 17, an input vector 1710 including three target path vectors is shown. A first target path vector is defined by element coordinate information a1 and recess coordinate information b1, a second target path vector is defined by element coordinate information a2 and recess coordinate information b2, and a third target path vector is defined by element coordinate information a3 and recess coordinate information b3.

An output vector 1720 includes f1, f2, f3, and f4 that are four pieces of output frequency information of the four wave energy generators 130. When there are two wave energy generators 130, the output vector 1720 will include two pieces of output frequency information f1 and f2.

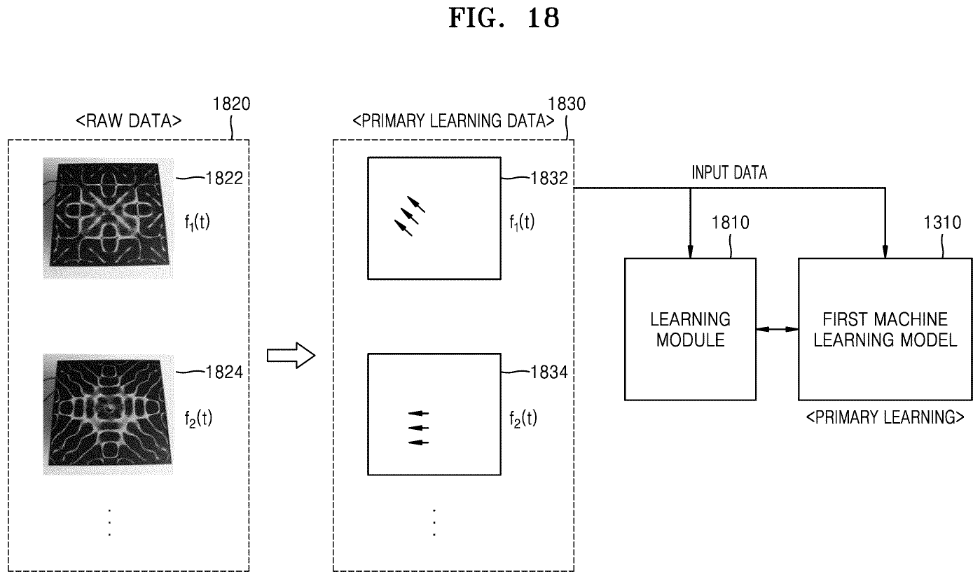

FIG. 18 is a diagram illustrating a process of learning of a first machine learning model, according to an embodiment.

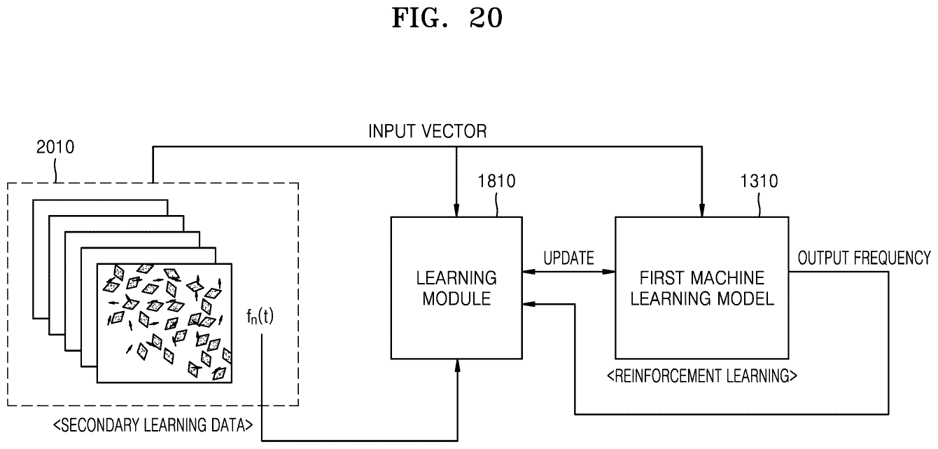

According to an embodiment, a first machine learning model 1310 may learn through a primary learning process and a secondary learning process. The primary learning process is a learning process using primary learning data. The secondary learning process is a learning process of reinforcing, by using secondary learning data, the first machine learning model 1310 that has firstly learned. In the disclosure, the primary learning process will be described with reference to FIG. 18 and the secondary learning process will be described with reference to FIG. 20.

First, the primary learning process will be described with reference to FIG. 18.

Learning of the first machine learning model 1310 may be performed by a learning module 1810. The learning module 1810 receives learning data, and learns and updates the first machine learning model 1310.

The first machine learning model 1310 according to an embodiment applies wave energy of a preset frequency to the cartridge 120, obtains a vector field representing the movement of a micro element, and collects primary learning data 1830 including the frequency and the vector field.

According to an embodiment, a learning condition of the first machine learning model 1310 is determined using simulation data using a Chladni pattern for each frequency.

Raw data 1820 obtained by calculating the Chladni pattern represents particle movement patterns 1822 and 1824 according to the Chladni pattern with respect to frequency f₁ and f₂. When calculating the Chladni pattern, the mass and shape of the micro element may be applied. Simulation data may be generated from the raw data 1820, and the simulation data may be used to determine learning conditions of the first machine learning model 1310.

The primary learning data 1830 includes frequency information f₁ and f₂ and vector fields 1832 and 1834 respectively corresponding to the frequency information f₁ and f₂. The primary learning data 1830 may be experimentally collected in advance. In addition, the primary learning data 1830 may be additionally obtained through augmentation processing of experimental data.

The learning module 1810 trains the first machine learning model 1310 by using the primary learning data 1830. The learning module 1810 updates the first machine learning model 1310 by using the first learning data 1830 to perform the first learning process. The learning module 1810 may perform the first learning process by using the PPO algorithm.

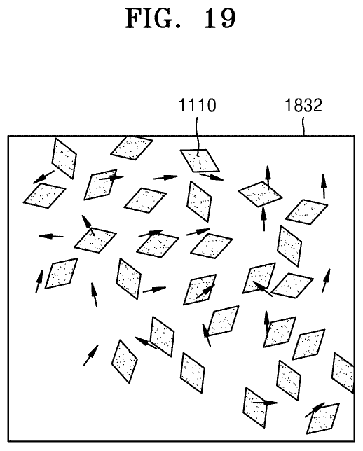

FIG. 19 is a diagram illustrating a vector field according to an embodiment.

According to an embodiment, first learning data may be collected based on a first image captured by photographing a movement of an actual micro element according to a frequency of wave energy. A learning data collection device (not shown) obtains a first image for a plurality of frequency combinations of wave energy. The learning data collection device tracks the movement of a micro element 1110 from the first image. The learning data collection device may obtain a vector field 1832 by tracking the optical flow of the micro element 1110. The learning data collection device tracks an optical flow by tracking the pixel movement of an object corresponding to the micro element 1110. The learning data collection device generates the vector field 1832 representing the optical flow in a vector form. The learning data collection device analyzes two consecutive images to track the optical flow and generates the vector field 1832.

According to an embodiment, an optical flow may be collected for each frequency combination of wave energy, and learning data may be collected until the optical flow for all combinations is filled.

Primary learning data may include one or a combination of data calculated based on the Chladni pattern and data generated by tracing the optical flow.

FIG. 20 is a diagram illustrating a process of performing secondary learning, according to an embodiment.

According to an embodiment, a secondary learning process for reinforcement learning of a first machine learning model 1310 for which primary learning has been completed is performed. A learning module 1810 collects secondary learning data 2010 including a vector field and frequency information from the element transfer device 100. The element transfer device 100 generates a vector field from a first image captured by the camera 140. Also, frequency information for each vector field is generated. The learning module 1810 inputs the second learning data 2010 to the first machine learning model 1310 and obtains an output frequency output from the first machine learning model 1310. The learning module 1810 compares the frequency information of the second learning data 2010 with an output frequency, and updates the first machine learning model 1310 based on the comparison result. The learning module 1810 calculates an error value between the frequency information of the second training data 2010 and the output frequency, and updates the first machine learning model 1310 based on the error value.

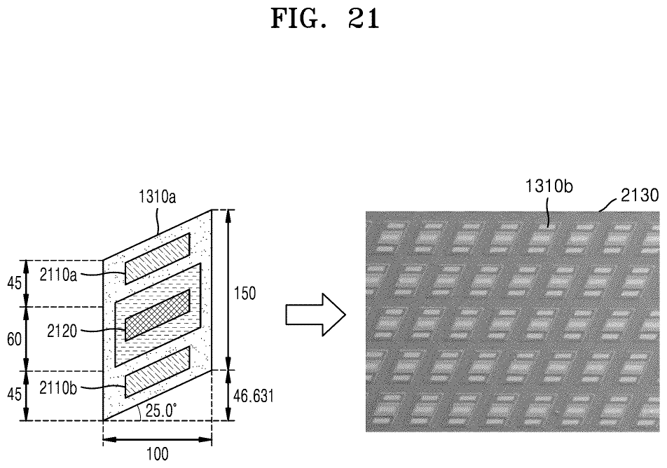

FIG. 21 is a diagram illustrating the structure of a micro element 1310a according to an embodiment.

According to an embodiment, the micro element 1310a may correspond to an LED chip having an asymmetric structure in a parallelogram shape. The micro element 1310a has a 180-degree symmetry, and left and right sides may be distinguished from each other. However, when the top and the bottom of the micro element 1310a are reversed, it is impossible to distinguish the micro element 1310a. According to an embodiment, the micro element 1310a includes a cathode electrode 2120 disposed in the center and two anode electrodes 2110a and 2110b disposed above and below the cathode electrode 2120, respectively. Due to this electrode structure, even if the micro element 1310a is upside down, current applied to the anode electrodes 2110a or 2110b may supply current to the cathode electrode 2120 of the micro element 1310a in a forward direction.

The micro element 1310a may be manufactured by forming an electrode on a wafer having a GaN LED epitaxial layer grown on a sapphire substrate according to a general fabrication process. The size indicated in FIG. 21 is a value in micro units and represents the size of the micro element 1310a according to an example. In addition, the micro element 1310a may have a thickness of 80 μm and a size of 150 μm×154 μm.

An image 2130 is an image captured by photographing the cartridge 120 in which the micro element 1310a is disposed. As shown in image 2130, the micro element 1310a may be transferred to an element recess on the cartridge 120 and arranged on the cartridge 120.

FIG. 22 is a diagram illustrating the structure of a micro element 1310B according to an embodiment.

According to an embodiment, the micro element 1310b may have a pentagonal shape in which one vertex is removed from a rectangular structure. The micro element 1310b has an asymmetric structure in which top, bottom, left, and right sides are distinguished from each other. The micro element 1310b includes a first electrode 2210 and a second electrode 2220. One of the first electrode 2210 and the second electrode 2220 may correspond to a cathode electrode, and the other may correspond to an anode electrode. The positions of electrodes may be configured like a general lateral chip or flip chip. The lateral chip and the flip chip are chips each having a structure in which electrodes are in one plane, and the micro element 1310b may have an electrode structure that is the same as that of the lateral chip or the flip chip.

The size of the micro element 1310b shown in FIG. 22 is a size according to an example. The micro element 1310b may have a thickness of 6 μm or less. The micro element 1310b may correspond to an LED chip. The micro element 1310b may be fabricated by forming a GaN epitaxial layer on a sapphire substrate and removing one vertex by using a laser-lift-off (LLO) method.

An image 2230 is an image captured by photographing the micro element 1310b arranged on the cartridge 120. As a result of an experiment, it was confirmed that, when 100*100 micro elements 1310b are arranged on a silicon substrate, up to 99% of the micro elements 1310b may be arranged within 30 minutes. In the experiment, an element transfer device 100 having the structure shown in FIG. 4 was used. In addition, in the experiment, the micro elements 1310b may be seated in element recesses formed on the cartridge 120 by moving the micro elements 1310b from left to right and from right to left by using the two wave energy generators 130. The filling rate over time showed results as shown in FIG. 8.

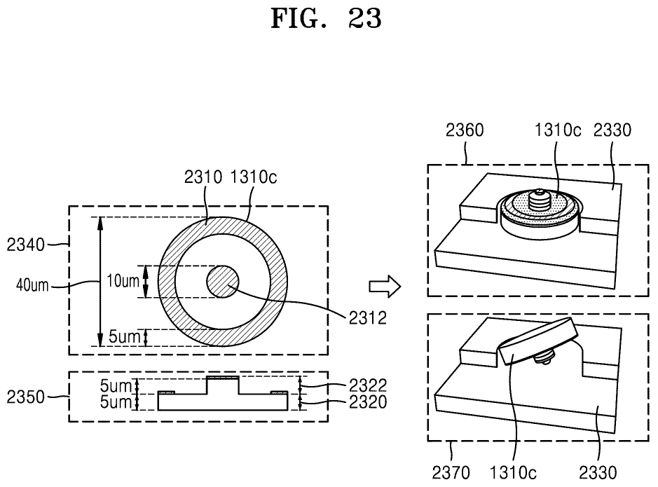

FIG. 23 is a diagram illustrating the structure of a micro element 1310c according to an embodiment. In FIG. 23, reference numeral 2340 represents a top view of the micro element 1310c, and reference numeral 2350 represents a side cross-sectional view of the micro element 1310c.

The micro element 1310c according to an embodiment may have a disk-type shape. The micro element 1310c includes a disk 2320 and a protrusion 2322. The disk 2320 and the protrusion 2322 are integrally formed as a single body. The micro element 1310c includes a first electrode 2310 on the periphery of the upper surface of the disk 2320 and a second electrode 2312 on the upper surface of the protrusion 2322. The first electrode 2310 may be a p-type electrode or cathode, and the second electrode 2312 may be an n-type electrode or anode. FIG. 23 shows an exemplary size of the micro element 1310c.

Because the bottom surface of the micro element 1310c is circular, the micro element 1310c may be easily seated in an element recess and is very advantageous for bonding. The micro element 1310c has a step between the first electrode 2310 and the second electrode 2312, and thus, when the micro element 1310c is arranged on the cartridge 120, the top and bottom of the micro element 1310c may be distinguished from each other. That is, it is possible to control the magnitude of wave energy so that a stepped electrode portion faces upward. The micro element 1310c may induce detrapping when the stepped electrode portion faces downward, and thus, chips may be easily arranged in a desired manner. As shown at 2360, the micro element 1310c may be seated in an element recess of a substrate 2330 of the cartridge 120 in a forward direction. When the top and bottom of the micro element 1310c are reversed to approach the element recess, the micro element 1310c is not seated in the element recess as in 2370.

The cartridge 120 may include a circular element recess. In the experiment, the cartridge 120 was made of silicon, and the depth of the element recess was set to 9 μm, which is greater than the thickness (less than 7 μm) of the micro element 1310c. In the experiment, it was confirmed that 100*100 micro elements 1310c were aligned up to 90% within 5 minutes by using the element transfer device 100 having the structure shown in FIG. 4 and using wave energies of 120 Hz and 100 Hz.

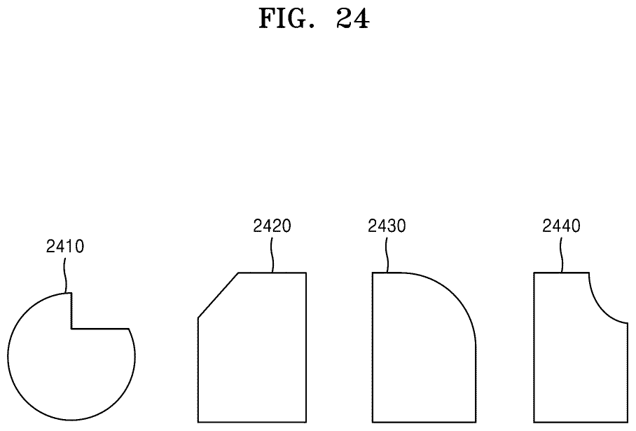

FIG. 24 is a diagram illustrating a shape of a micro element according to an embodiment.

According to an embodiment, the micro element may have various shapes 2410, 2420, 2430, and 2440 as shown in FIG. 24. Because the shapes shown in FIG. 24 have an asymmetric structure, it is easy to distinguish top, bottom, left, and right thereof, and thus, the micro element 1310 is seated in an element recess in a forward direction. The element recess of the cartridge 120 may be formed to correspond to the shape of the micro element 1310.

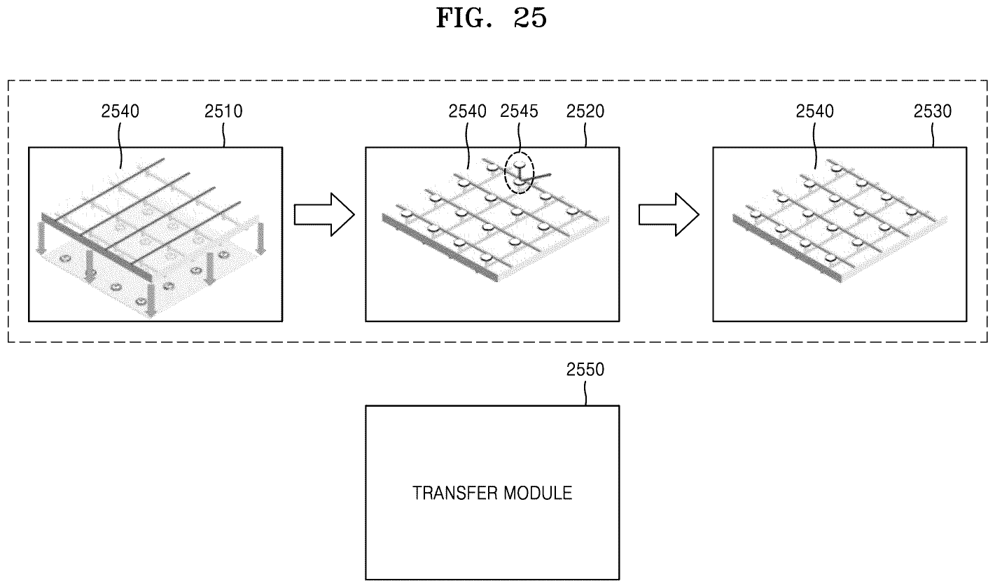

FIG. 25 is a diagram illustrating a process of transferring micro elements from a cartridge to a substrate and bonding the micro elements to the substrate, according to an embodiment.

According to an embodiment, in Operation 2510, the micro elements transferred to the cartridge 120 are transferred to a substrate 2540. The surface of the cartridge 120 on which the micro elements are disposed and the upper surface of the substrate 2540 come into contact with each other, and thus, the micro elements of the cartridge 120 are transferred to the substrate 2540. The substrate 2540 may correspond to, for example, a substrate of a display panel, and the micro elements may correspond to micro LED chips.

Next, in Operation 2520, a bonding process for the micro elements transferred to the substrate 2540 is performed. When transfer is omitted on the substrate 2540 or a defect occurs during the transfer or bonding process, a rework i process 2545 s performed to transfer and bond the micro elements again to corresponding points.

When the bonding and rework processes are completed, as in Operation 2530, the substrate 2540 onto which the micro elements are transferred is fabricated.

Operations 2510, 2520, and 2530 described above may be performed by a transfer module 2550. The transfer module 2550 may correspond to a device used in a process of transferring an element.

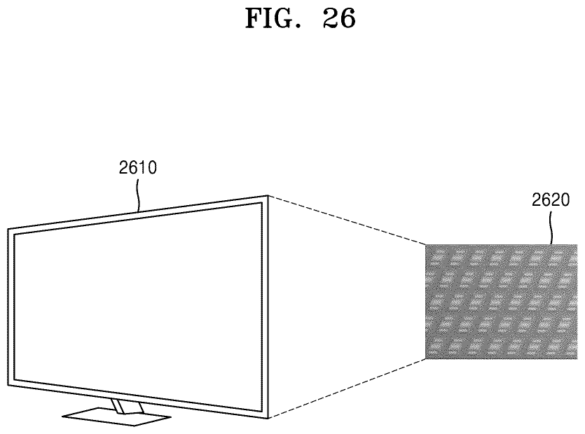

FIG. 26 is a diagram illustrating a display device according to an embodiment.

According to an embodiment, a display device 2610 including a substrate 2620 produced using the element transfer device 100 according to an embodiment is provided. The substrate 2620 of the display device 2610 may include micro LEDs transferred using the element transfer device 100.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. An element transfer device comprising:
a cartridge including a plurality of element recesses each having a shape corresponding to a shape of a micro element;
at least one wave energy generator configured to supply wave energy having a certain frequency to the cartridge;
a camera configured to photograph an arrangement state of the micro element on the cartridge; and
a processor configured to control the at least one wave energy generator,
wherein the processor is further configured to:
primarily arrange a plurality of micro elements in the plurality of element recesses by supplying the wave energy to the cartridge accommodating the plurality of micro elements disposed in a fluid,
obtain a first image by photographing the cartridge, for which the primary arrangement is completed, by using the camera, and
based on the first image, control a waveform and a frequency of the wave energy supplied from the at least one wave energy generator and control a secondary arrangement of arranging the micro elements in remaining element recesses in which the micro elements are not disposed, from among the plurality of element recesses.

2. The element transfer device of claim 1, wherein the processor is further configured to:
input an input vector obtained from the first image to a first machine learning model, obtain output frequency information output from the first machine learning model, and
control the at least one wave energy generator to output wave energy based on the output frequency information.

3. The element transfer device of claim 2, wherein the processor is further configured to:
recognize at least one remaining micro element not disposed in an element recess from the first image,
recognize at least one remaining element recess in which a micro element is not disposed, and
input the input vector including a position of the at least one remaining micro element and a position of the at least one remaining element recess to the first machine learning model and obtain the output frequency information output from the first machine learning model.

4. The element transfer device of claim 2, wherein the first machine learning model is a model trained using at least one of Proximal Policy Optimization (PPO), Trust Region Policy Optimization (TRPO), Advantage Actor Critic (A2C), and Deep Q Network (DQN) algorithms.

5. The element transfer device of claim 2, wherein the first machine learning model is primarily trained using first learning data,
wherein the processor is further configured to:
obtain a vector field representing movement of the plurality of micro elements according to an output frequency of the at least one wave energy generator from the first image, and
update the first machine learning model by performing reinforcement learning on the first machine learning model by using secondary learning data including a vector field of the plurality of micro elements and an output frequency of the at least one wave energy generator.

6. The element transfer device of claim 5, wherein the processor is further configured to:
calculate an error between a vector field of the plurality of micro elements corresponding to an input vector of the first machine learning model and a vector field of the plurality of micro elements obtained from the first image,
calculate an evaluation compensation based on the error, and
perform reinforcement learning on the first machine learning model based on the evaluation compensation.

7. The element transfer device of claim 1, wherein the processor is further configured to:
obtain the first image for each first period,
determine a waveform and an output frequency of wave energy output from the at least one wave energy generator, based on the first image for each first period, and
control the at least one wave energy generator to output wave energy having the determined waveform and the output frequency.

8. The element transfer device of claim 1, wherein the at least one wave energy generator includes a plurality of wave energy generators arranged around the cartridge,
wherein the processor is further configured to control a waveform and an output frequency of the wave energy of each of the plurality of wave energy generators.

9. The element transfer device of claim 1, wherein each of the plurality of micro elements is 180-degree symmetric, and includes a cathode electrode at a center of the micro element, a first anode electrode on an upper side of the cathode electrode, and a second anode electrode on a lower side of the cathode electrode, and
the plurality of element recesses each have shapes corresponding to shapes of the plurality of micro elements.

10. The element transfer device of claim 1, wherein each of the plurality of micro elements has an asymmetric shape in which top, bottom, left, and right sides are distinguished from each other, and includes one anode and one cathode, and
the plurality of element recesses each have shapes corresponding to shapes of the plurality of micro elements.

11. The element transfer device of claim 1, wherein each of the plurality of micro elements includes a circular disk and a protrusion in a center of a first surface of the circular disk,
a first electrode is formed on the protrusion and a second electrode is formed on the circular disk, and
the plurality of element recesses each have shapes corresponding to a shape of a second surface of the circular disk opposite to the first surface.

12. The element transfer device of claim 1, wherein the cartridge includes an align key formed on the cartridge to identify an arrangement state of the cartridge,
wherein the processor is further configured to recognize the align key of the cartridge from the first image and obtain image data of an area corresponding to the cartridge based on the recognized align key.

13. The element transfer device of claim 1, wherein the wave energy corresponds to an acoustic streaming signal.

14. The element transfer device of claim 1, further comprising an element transfer jig including at least one hole and configured to transfer the plurality of micro elements onto the cartridge through the hole, wherein the element transfer jig is a chip transfer jig.

15. The element transfer device of claim 14, further comprising an element dispersing device configured to disperse the plurality of micro elements by tilting the cartridge,
wherein the processor is further configured to:
after the plurality of micro elements are supplied to a fluid on the cartridge through the element transfer jig, control the element dispersing device to disperse the plurality of micro elements by tilting the cartridge, and
perform primary arrangement after the plurality of micro elements are dispersed on the cartridge by the element dispersing device.

16. The element transfer device of claim 1, wherein the processor is further configured to:
determine whether a transfer of the micro element to each of the plurality of element recesses has been completed based on the first image captured by photographing the cartridge in which the micro elements are secondarily arranged, and
repeat the secondary arrangement until the transfer of the micro element to each of the plurality of element recesses is completed.

17. The element transfer device of claim 16, further comprising a transfer module configured to transfer the plurality of micro elements arranged in the cartridge to a substrate,
wherein the transfer module is further configured to:
remove remaining micro elements on the cartridge where arrangement of the micro elements is completed,
place the substrate on the cartridge to transfer the plurality of micro elements arranged on the cartridge to the substrate, and
bond the micro elements transferred to the substrate to the substrate.

18. The element transfer device of claim 1, wherein the plurality of micro elements correspond to light-emitting diode (LED) elements, respectively, and
the LED elements arranged on the cartridge are transferred to a substrate of a display device.

19. The element transfer device of claim 1, wherein the plurality of micro elements each have a size of about 100 micrometers (μm) or less.

20. A display device comprising a light-emitting diode (LED) substrate manufactured by arranging a plurality of LED elements on a cartridge by using the element transfer device of claim 1 and transferring the plurality of LED elements arranged on the cartridge to a substrate,
wherein the plurality of LED elements each have a size of about 100 micrometers (μm) or less.
